(19) United States
(12) Patent Application Publication
(10) Pub. No.: US 2026/0173584 A1
(43) Pub. Date: Jun. 18, 2026

(54) LIGHT-EMITTING DIODE STRUCTURE AND MANUFACTURING METHOD THEREOF

(71) Applicant: ASUSTeK COMPUTER INC., Taipei City (TW)

(72) Inventors: Ching-Hsin Lin, Taipei City (TW); Chin-An Tseng, Taipei City (TW); Chia-Lei Yu, Taipei City (TW); Jian-Jang Huang, Taipei City (TW); Yuan-Chao Wang, Taipei City (TW); Cheng-Jui Yu, Taipei City (TW)

(73) Assignee: ASUSTeK COMPUTER INC., Taipei City (TW)

(21) Appl. No.: 19/243,650

(22) Filed: Jun. 19, 2025

(30) Foreign Application Priority Data
Dec. 13, 2024 (TW) 113148559

(51) Int. Cl. H10H 20/01; H10H 20/816; H10H 20/84

(52) U.S. Cl. CPC H10H 20/017; H10H 20/032; H10H 20/034; H10H 20/8162; H10H 20/84

(57) ABSTRACT

A manufacturing method of a light-emitting diode structure, including: providing a substrate; forming a first type semiconductor layer, an active layer, and a second type semiconductor layer on the substrate in sequence; etching a part of the second semiconductor layer, a part of the active layer, and a part of the first semiconductor layer in sequence to expose an etched side surface of the second type semiconductor layer, an etched side surface of the active layer, and an etched side surface of the first semiconductor layer; and using water vapor to penetrate at least a part of the etched side surfaces, so as to from metal oxide in at least a part of an edge region of the second type semiconductor layer, an edge region of the active layer, and at least a part of an edge region of the first semiconductor layer. A light-emitting diode structure is also provided.

### CROSS-REFERENCE TO RELATED APPLICATION

This application claims the priority benefit of Taiwan application serial no. 113148559, filed on Dec. 13, 2024. The entirety of the above-mentioned patent application is hereby incorporated by reference herein and made a part of this specification.

### BACKGROUND

### Technical Field

The disclosure relates to a light-emitting diode (LED) structure and a manufacturing method thereof.

### Description of Related Art

Light-emitting diodes have gradually become a widely used next-generation light source due to advantages such as energy saving, high reliability, and long service life. The main structure of a light-emitting diode includes an N-type semiconductor layer, a P-type semiconductor layer, and a multiple quantum well layer configured between the N-type semiconductor layer and the P-type semiconductor layer. In some manufacturing processes of light-emitting diode structures, parts of the P-type semiconductor layer, parts of the multiple quantum well layer, and parts of the N-type semiconductor layer are etched to form a light-emitting platform.

The light emission of a light-emitting diode is generated by the recombination of electrons and holes in the multiple quantum well layer. However, the side surfaces of the light-emitting platform are etched side surfaces that have lattice defects. When electrons and holes recombine at the etched side surfaces of the multiple quantum well layer, the lattice defects cause the recombination of electrons and holes to not emit light properly. Therefore, the etched side surfaces reduce the light-emission efficiency of the light-emitting diode.

### SUMMARY

The disclosure provides a manufacturing method of a light-emitting diode structure, which may effectively improve a luminous efficiency of the light-emitting diode structure.

The disclosure also provides a light-emitting diode structure, which facilitates the enhancement of the luminous efficiency.

An embodiment of the disclosure provides a manufacturing method of a light-emitting diode structure. The manufacturing method includes the following steps. A substrate is provided. A first type semiconductor layer, an active layer, and a second type semiconductor layer are sequentially formed on the substrate. A part of the second type semiconductor layer, a part of the active layer, and a part of the first type semiconductor layer are sequentially etched to expose an etched side surface of the second type semiconductor layer, an etched side surface of the active layer, and an etched side surface of the first type semiconductor layer. A water vapor is used to penetrate at least a part of the etched side surface of the second type semiconductor layer, the etched side surface of the active layer, and at least a part of the etched side surface of the first type semiconductor layer, so as to form a metal oxide in at least a part of an edge region of the second type semiconductor layer, an edge region of the active layer, and at least a part of an edge region of the first type semiconductor layer.

An embodiment of the disclosure provides a light-emitting diode structure, including a substrate, a first type semiconductor layer, an active layer, a second type semiconductor layer, and a metal oxide layer. The first type semiconductor layer is configured on the substrate, the active layer is configured on the first type semiconductor layer, the second type semiconductor layer is configured on the active layer, and the metal oxide layer directly contacts at least a part of an edge of the first type semiconductor layer, an edge of the active layer, and at least a part of an edge of the second type semiconductor layer.

In the manufacturing method of the light-emitting diode structure of the embodiment of the disclosure, the metal oxide is formed in at least a part of an edge region of the second type semiconductor layer, an edge region of the active layer, and at least a part of an edge region of the first type semiconductor layer. A high impedance of the metal oxide may prevent electrons and holes from recombining at the etched side surfaces without emitting light, thereby concentrating electrons and holes in the central region away from the etched side surfaces to recombine and emit light. This increases the probability of radiative recombination of electron-hole pairs in the active layer, thereby improving luminous efficiency. In the light-emitting diode structure of the embodiment of the disclosure, the metal oxide layer directly contacts at least a part of an edge of the first type semiconductor layer, an edge of the active layer, and at least a part of an edge of the second type semiconductor layer. The metal oxide layer is formed by oxidizing at least a part of the edge region of the first type semiconductor layer, the edge region of the active layer, and at least a part of the edge region of the second type semiconductor layer. Due to the high impedance of the metal oxide layer, electrons and holes may be effectively prevented from recombining at the side surfaces of the semiconductor stack structure without emitting light. Instead, electrons and holes are concentrated in the central region away from the side surfaces of the semiconductor stack structure to recombine and emit light. This increases the probability of radiative recombination of electron-hole pairs in the active layer, thereby improving luminous efficiency.

### BRIEF DESCRIPTION OF THE DRAWINGS

FIGS. 1A to 1H are cross-sectional schematic diagrams illustrating the process flow of the manufacturing method for the light-emitting diode structure according to an embodiment of the disclosure.

FIG. 2 is a cross-sectional schematic diagram of the light-emitting diode structure according to another embodiment of the disclosure.

FIG. 3 is a cross-sectional schematic diagram of the light-emitting diode structure according to yet another embodiment of the disclosure.

FIG. 4 is a cross-sectional schematic diagram of the light-emitting diode structure according to still another embodiment of the disclosure.

### DESCRIPTION OF THE EMBODIMENTS

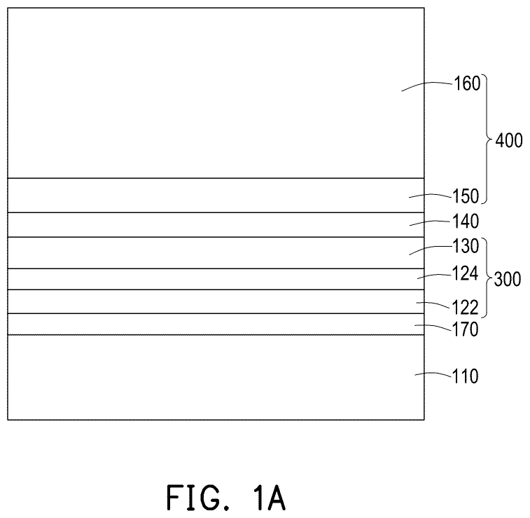

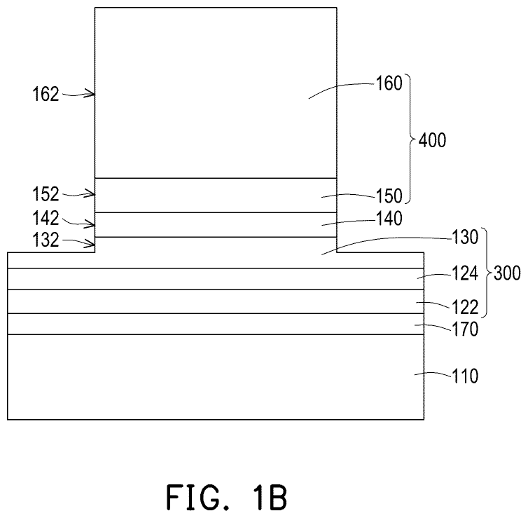

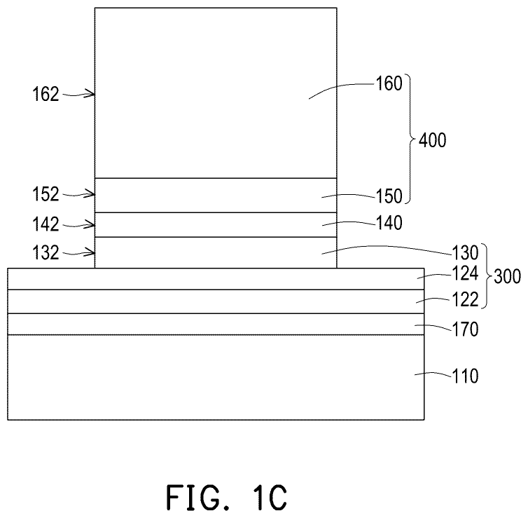

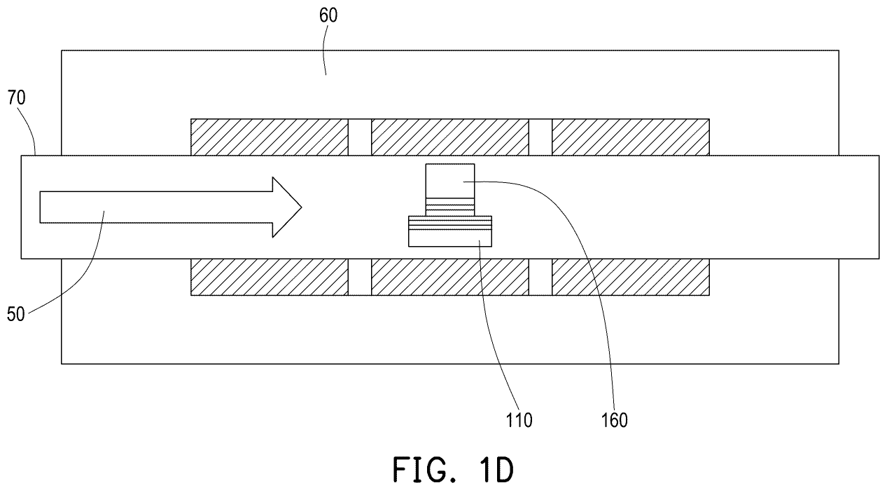

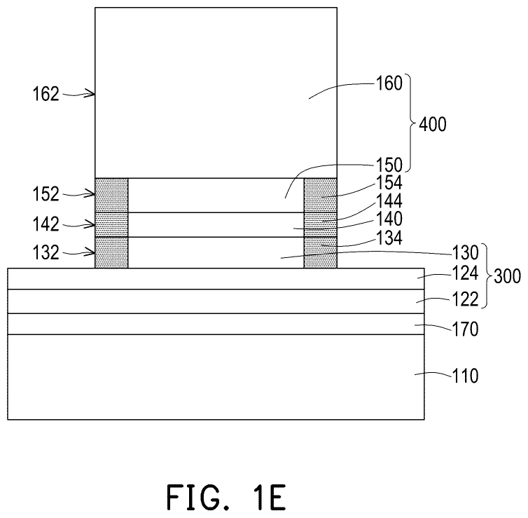

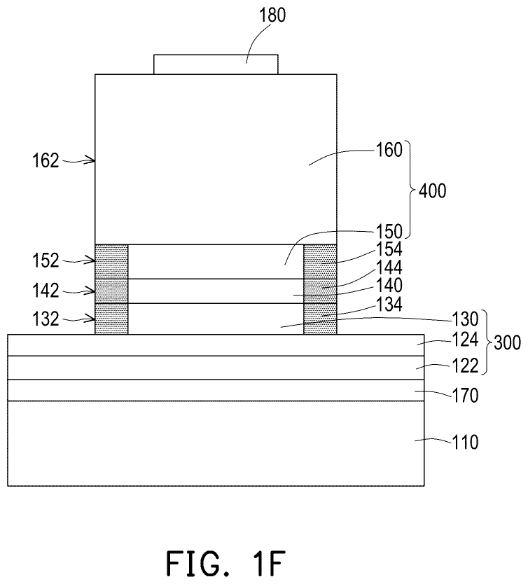

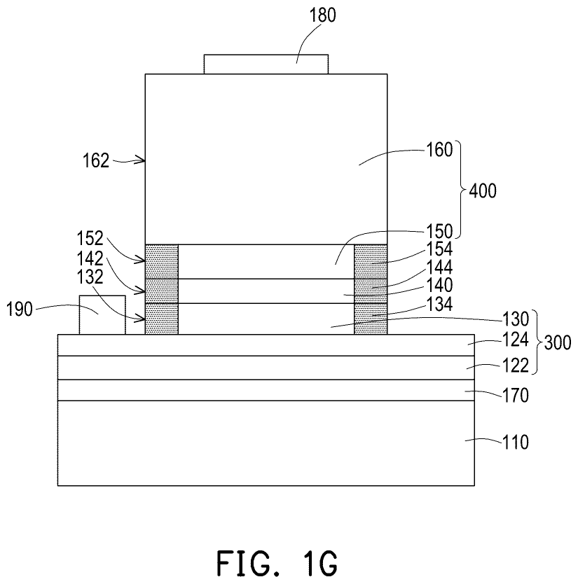

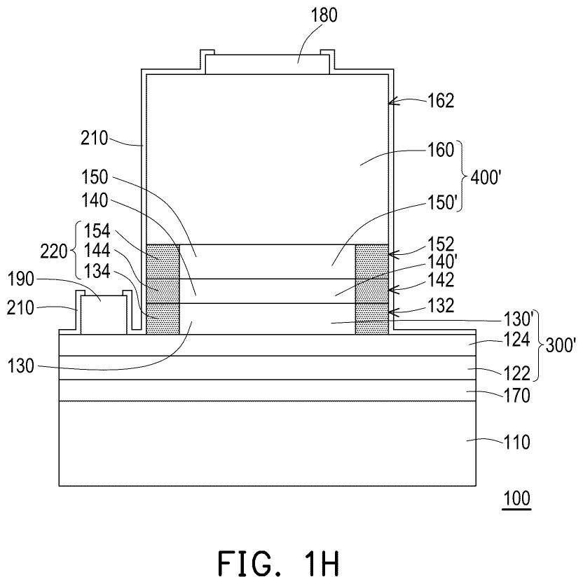

FIGS. 1A to 1H are cross-sectional schematic diagrams illustrating the process flow of the manufacturing method for the light-emitting diode structure according to an embodiment of the disclosure. The manufacturing method of the light-emitting diode structure in this embodiment includes the following steps. First, referring to FIG. 1A, a substrate 110 is provided. Then, a first type semiconductor layer 300, an active layer 140, and a second type semiconductor layer 400 are sequentially formed on the substrate 110. One of the first type and the second type is N-type, and the other is P-type. In this embodiment, the first type is N-type, and the second type is P-type. Before forming the first type semiconductor layer 300, a buffer layer 170 may optionally be formed on the substrate 110, and then the first type semiconductor layer 300 is formed on the buffer layer 170. In this embodiment, the first type semiconductor layer 300 includes at least one first type semiconductor sublayer 120 (in FIG. 1A, a first type semiconductor sublayer 122 and a first type semiconductor sublayer 124 are used as examples, formed sequentially) and a first type cladding layer 130. The first type semiconductor sublayers 122 and 124 are formed on the substrate 110, for example, on the buffer layer 170, and the first type cladding layer 130 is formed on the first type semiconductor sublayer 124.

In this embodiment, the second type semiconductor layer 400 includes a second type cladding layer 150 and at least one second type semiconductor sublayer (in FIG. 1A, a second type semiconductor sublayer 160 is used as an example). The second type cladding layer 150 is formed on the active layer 140, and the second type semiconductor sublayer 160 is formed on the second type cladding layer 150.

In this embodiment, the material of the substrate 110 is, for example, gallium arsenide. The material of the buffer layer 170 is, for example, gallium arsenide. The material of the first type semiconductor sublayer 122 is, for example, N-type gallium indium phosphide. The material of the first type semiconductor sublayer 124 is, for example, N-type gallium arsenide. The material of the first type cladding layer 130 is, for example, N-type aluminum gallium indium phosphide. The material of the second type cladding layer 150 is, for example, P-type aluminum gallium indium phosphide. The material of the second type semiconductor sublayer 160 is, for example, P-type gallium phosphide. However, the disclosure is not limited to these materials.

In this embodiment, the active layer 140 is, for example, a multiple quantum well layer, which is formed by alternately stacking multiple well layers and multiple barrier layers. The material of the well layer is, for example, aluminum gallium indium phosphide, and the material of the barrier layer is, for example, gallium indium phosphide. However, the disclosure is not limited to these materials.

Next, referring to FIGS. 1B and 1C, a part of the second type semiconductor layer 400, a part of the active layer 140, and a part of the first type semiconductor layer 300 are sequentially etched to expose the etched side surface of the second type semiconductor layer 400, the etched side surface of the active layer 140, and the etched side surface of the first type semiconductor layer 300. Specifically, in this embodiment, a part of the second type semiconductor sublayer 160, a part of the second type cladding layer 150, a part of the active layer 140, and a part of the first type cladding layer 130 are sequentially etched to expose an etched side surface 162 of the second type semiconductor sublayer 160, an etched side surface 152 of the second type cladding layer 150, an etched side surface 142 of the active layer 140, and an etched side surface 132 of the first type cladding layer 130. In this embodiment, the steps of sequentially etching a part of the second type semiconductor sublayer 160, a part of the second type cladding layer 150, a part of the active layer 140, and a part of the first type cladding layer 130 may include first using a dry etching method to etch a part of the second type semiconductor sublayer 160, a part of the second type cladding layer 150, a part of the active layer 140, and a part of the first type cladding layer 130 without etching to the bottom of the first type cladding layer 130 (as shown in FIG. 1B). Then, a wet etching method is used to etch a part of the first type cladding layer 130 until the top of the first type semiconductor sublayer 120 is exposed (as shown in FIG. 1C). However, in other embodiments, the steps of sequentially etching a part of the second type semiconductor sublayer 160, a part of the second type cladding layer 150, a part of the active layer 140, and a part of the first type cladding layer 130 may also be performed entirely using a dry etching method or entirely using a wet etching method until the top of the first type semiconductor sublayer 120 is exposed or until at least a part of the first type semiconductor sublayer 120 is further etched.

Next, referring to FIGS. 1D and 1E, a water vapor 50 is used to penetrate at least a part of the etched side surface of the second type semiconductor layer 400, the etched side surface of the active layer 140, and at least a part of the etched side surface of the first type semiconductor layer 300, so as to form a metal oxide in at least a part of an edge region of the second type semiconductor layer 400, an edge region of the active layer 140, and at least a part of an edge region of the first type semiconductor layer 300. In this embodiment, for example, water vapor 50 penetrates the etched side surface 152 of the second type cladding layer 150, the etched side surface 142 of the active layer 140, and the etched side surface 132 of the first type cladding layer 130, so as to form a metal oxide in an edge region 154 of the second type cladding layer 150, an edge region 144 of the active layer 140, and an edge region 134 of the first type cladding layer 130. This metal oxide may include aluminum oxide. In this embodiment, the metal oxide is, for example, aluminum oxide. In an embodiment, the metal oxide includes aluminum oxide, indium oxide, gallium oxide, other metal oxides, or a combination thereof. In this embodiment, the step of using water vapor 50 to penetrate the etched side surface 152 of the second type cladding layer 150, the etched side surface 142 of the active layer 140, and the etched side surface 132 of the first type cladding layer 130 may be performed as shown in FIG. 1D. The entire structure shown in FIG. 1C is placed into a high-temperature furnace 60, specifically into a furnace tube 70 of the high-temperature furnace 60, and water vapor 50 is introduced into the furnace tube 70. When water vapor 50 penetrates the etched side surface 152 of the second type cladding layer 150, the etched side surface 142 of the active layer 140, and the etched side surface 132 of the first type cladding layer 130, forming a metal oxide in the edge regions 154, 144, and 134, the resulting structure is as shown in FIG. 1E.

Subsequently, referring to FIG. 1F, a first electrode 180 is formed on the second type semiconductor layer 400. In this embodiment, for example, the first electrode 180 is formed on the second type semiconductor sublayer 160. In an embodiment, the first electrode 180 includes a titanium layer and a gold layer sequentially stacked upward from the second type semiconductor sublayer 160. The titanium layer allows the first electrode 180 to form an ohmic contact with the second type semiconductor sublayer 160. Next, referring to FIG. 1G, a second electrode 190 is formed on the first type semiconductor layer 300. In this embodiment, for example, the second electrode 190 is formed on the first type semiconductor sublayer 120. In an embodiment, the second electrode 190 includes a nickel layer, a germanium layer, another nickel layer, and a gold layer sequentially stacked upward from the first type semiconductor sublayer 120, so as to form an ohmic contact between the second electrode 190 and the first type semiconductor sublayer 120.

Next, referring to FIG. 1H, a protective layer 210 is formed on the first type semiconductor layer 300, a side surface of the second electrode 190, the etched side surface of the first type semiconductor layer 300, the etched side surface of the active layer 140, the etched side surface of the second type semiconductor layer 400, the second type semiconductor layer 400, and a side surface of the first electrode 180. In this embodiment, for example, the protective layer 210 is formed on the first type semiconductor sublayer 120, a side surface of the second electrode 190, the etched side surface 132 of the first type cladding layer 130, the etched side surface 142 of the active layer 140, the etched side surface 152 of the second type cladding layer 150, the second type semiconductor sublayer 160, and a side surface of the first electrode 180. The protective layer 210 may also cover the edge of the upper surface of the first electrode 180 and the edge of the upper surface of the second electrode 190. The protective layer 210 is an insulating layer, and the material thereof is, for example, silicon oxide, silicon nitride, or other insulating materials. Thus, the light-emitting diode structure 100 of this embodiment may be completed. The light-emitting diode structure 100 of this embodiment includes a substrate 110, a first type semiconductor layer 300′, an active layer 140′, a second type semiconductor layer 400′, and a metal oxide layer 220. The first type semiconductor layer 300′ is configured on the substrate 110, the active layer 140′ is configured on the first type semiconductor layer 300′, the second type semiconductor layer 400′ is configured on the active layer 140′, and the metal oxide layer 220 directly contacts at least a part of an edge of the first type semiconductor layer 300′, an edge of the active layer 140′, and at least a part of an edge of the second type semiconductor layer 400′.

In this embodiment, the first type semiconductor layer 300′ includes at least one first type semiconductor sublayer (in this embodiment, the first type semiconductor sublayers 122 and 124 are used as examples) and a first type cladding layer 130′. The first type semiconductor sublayers 122 and 124 are configured on the substrate 110, and the first type cladding layer 130′ is configured on the first type semiconductor sublayers 122 and 124. The second type semiconductor layer 400′ includes a second type cladding layer 150′ and at least one second type semiconductor sublayer 160. The second type cladding layer 150′ is configured on the active layer 140′, and the second type semiconductor sublayer 160 is configured on the second type cladding layer 150′. In this embodiment, the metal oxide layer 220 directly contacts an edge of the first type cladding layer 130′, an edge of the active layer 140′, and an edge of the second type cladding layer 150′.

In this embodiment, the first type cladding layer 130′ is the part of the first type cladding layer 130 in FIG. 1E that has not been oxidized by water vapor 50. The active layer 140′ is the part of the active layer 140 in FIG. 1E that has not been oxidized by water vapor 50. The second type cladding layer 150′ is the part of the second type cladding layer 150 in FIG. 1E that has not been oxidized by water vapor 50. Additionally, the metal oxide layer 220 includes the edge region 134 of the first type cladding layer 130, the edge region 144 of the active layer 140, and the edge region 154 of the second type cladding layer 150 in FIG. 1E, all of which are oxidized by water vapor 50. In this embodiment, the material of the metal oxide layer 220 includes aluminum oxide. In an embodiment, the material of the metal oxide layer 220 includes aluminum oxide, indium oxide, gallium oxide, other metal oxides, or a combination thereof.

In the manufacturing method of the light-emitting diode structure in this embodiment, a metal oxide is formed in the edge region 154 of the second type cladding layer 150, the edge region 144 of the active layer 140, and the edge region 134 of the first type cladding layer 130. The high impedance of the metal oxide may prevent electrons and holes from recombining at the etched side surfaces 152, 142, and 132 without emitting light. Instead, electrons and holes are concentrated in the central region away from the etched side surfaces 152, 142, and 132 to recombine and emit light. This increases the probability of radiative recombination of electron-hole pairs in the active layer 140, thereby improving luminous efficiency. In the light-emitting diode structure 100 of this embodiment, the metal oxide layer 220 directly contacts the edge of the first type cladding layer 130′, the edge of the active layer 140′, and the edge of the second type cladding layer 150′. The metal oxide layer 220 is formed by oxidizing the edge region 132 of the first type cladding layer 130, the edge region 142 of the active layer 140, and the edge region 152 of the second type cladding layer 150. Due to the high impedance of the metal oxide layer 220, electrons and holes may be effectively prevented from recombining at the side surfaces of the semiconductor stack structure (i.e., the etched side surfaces 152, 142, and 132) without emitting light. Instead, electrons and holes are concentrated in the central region away from the side surfaces of the semiconductor stack structure (i.e., the etched side surfaces 152, 142, and 132) to recombine and emit light. This increases the probability of radiative recombination of electron-hole pairs in the active layer 140′, thereby improving luminous efficiency.

In the light-emitting diode structure 100 of this embodiment, the first electrode 180 is configured on the second type semiconductor sublayer 160, and the second electrode 190 is configured on the first type semiconductor sublayer 120. The protective layer 210 covers the first type semiconductor sublayer 120, a side surface of the second electrode 190, the metal oxide layer 220, the second type semiconductor sublayer 160, and a side surface of the first electrode 180. In this embodiment, the protective layer 210 may also cover the edge of the upper surface of the second electrode 190 and the edge of the upper surface of the first electrode 180, as shown in FIG. 1H. In this embodiment, the light emitted from the active layer 140′ is, for example, red light. However, in other embodiments, depending on the selection of different semiconductor materials and adjustments to parameters, the active layer 140′ may emit visible light of other wavelengths or colors, ultraviolet light, or infrared light. The disclosure is not limited to this.

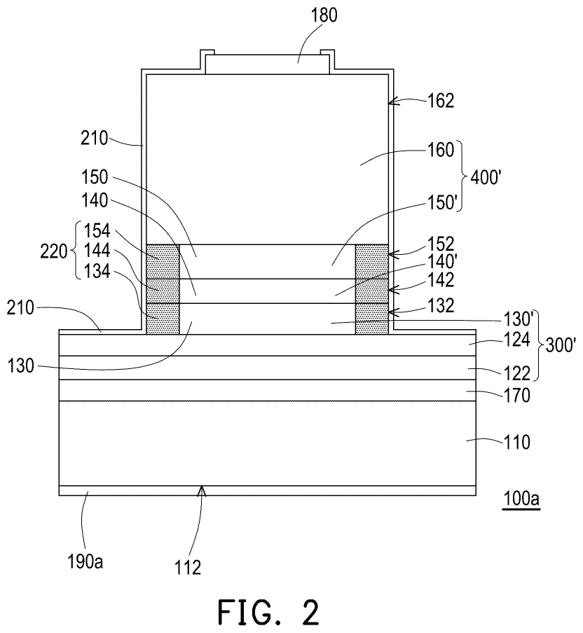

FIG. 2 is a cross-sectional schematic diagram of a light-emitting diode structure according to another embodiment of the disclosure. Referring to FIG. 2, a light-emitting diode structure 100a of this embodiment is similar to the light-emitting diode structure 100 shown in FIG. 1H, and the differences between the two are as follows. In the light-emitting diode structure 100a of this embodiment, the substrate 110 is a first type semiconductor substrate, such as an N-type gallium arsenide substrate. A second electrode 190a is configured on a surface 112 of the substrate 110 opposite to the active layer 140′. In the manufacturing method of the light-emitting diode structure of this embodiment, the step of forming the second electrode 190a involves forming the second electrode 190a on the surface 112 of the substrate 110 opposite to the active layer 140.

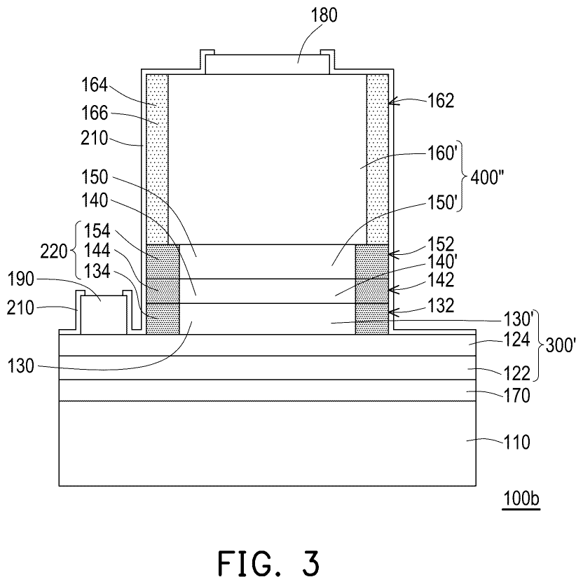

FIG. 3 is a cross-sectional schematic diagram of a light-emitting diode structure according to yet another embodiment of the disclosure. Referring to FIG. 3, a light-emitting diode structure 100b of this embodiment is similar to the light-emitting diode structure 100 shown in FIG. 1H, and the differences between the two are as follows. The light-emitting diode structure 100b of this embodiment further includes a metal oxide layer 164 that directly contacts an edge of a second type semiconductor sublayer 160′. In an embodiment, during the step shown in FIG. 1D, the water vapor 50 may also cause slight oxidation of the second type semiconductor sublayer 160. The second type semiconductor sublayer 160′ is the part of the second type semiconductor sublayer 160 that has not been oxidized by the water vapor 50, and the metal oxide layer 164 is an edge region 166 of the second type semiconductor sublayer 160 that has been oxidized by the water vapor 50. In other words, in this embodiment, the metal oxide layer includes both the metal oxide layer 220 and the metal oxide layer 164. This metal oxide layer directly contacts the entire side surface of a second type semiconductor layer 400″.

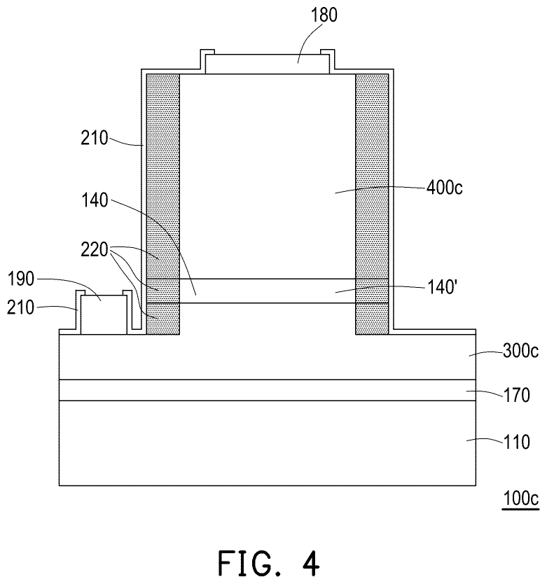

FIG. 4 is a cross-sectional schematic diagram of a light-emitting diode structure according to still another embodiment of the disclosure. Referring to FIG. 4, a light-emitting diode structure 100c of this embodiment is similar to the light-emitting diode structure 100 shown in FIG. 1H, and the differences between the two are as follows. In the light-emitting diode structure 100c of this embodiment, a first type semiconductor layer 300c does not include a first type cladding layer, and a second type semiconductor layer 400c does not include a second type cladding layer. The first type semiconductor layer 300c and the second type semiconductor layer 400c are directly disposed on two opposite sides of the active layer 140′. The first type semiconductor layer 300c and the second type semiconductor layer 400c may each be a single semiconductor layer or formed by stacking two or more semiconductor sublayers. The metal oxide layer 220 directly contacts at least a part of an edge of the first type semiconductor layer 300c, an edge of the active layer 140′, and at least a part of an edge (in FIG. 4, the entirety is shown as an example) of the second type semiconductor layer 400c.

In summary, in the manufacturing method of the light-emitting diode structure according to the embodiments of the disclosure, a metal oxide is formed in at least a part of an edge region of the second type semiconductor layer, an edge region of the active layer, and at least a part of an edge region of the first type semiconductor layer. The high impedance of the metal oxide may prevent electrons and holes from recombining at the etched side surfaces without emitting light. Instead, electrons and holes are concentrated in the central region away from the etched side surfaces to recombine and emit light. This increases the probability of radiative recombination of electron-hole pairs in the active layer, thereby improving luminous efficiency. In the light-emitting diode structure of the embodiments of the disclosure, the metal oxide layer directly contacts at least a part of an edge of the first type semiconductor layer, an edge of the active layer, and at least a part of an edge of the second type semiconductor layer. The metal oxide layer is formed by oxidizing at least a part of the edge region of the first type semiconductor layer, the edge region of the active layer, and at least a part of the edge region of the second type semiconductor layer. Due to the high impedance of the metal oxide layer, electrons and holes may be effectively prevented from recombining at the side surfaces of the semiconductor stack structure without emitting light. Instead, electrons and holes are concentrated in the central region away from the side surfaces of the semiconductor stack structure to recombine and emit light. This increases the probability of radiative recombination of electron-hole pairs in the active layer, thereby improving luminous efficiency.

What is claimed is:

1. A manufacturing method of a light-emitting diode structure, comprising:
providing a substrate;
forming a first type semiconductor layer, an active layer, and a second type semiconductor layer on the substrate in sequence;
etching a part of the second type semiconductor layer, a part of the active layer, and a part of the first type semiconductor layer in sequence to expose an etched side surface of the second type semiconductor layer, an etched side surface of the active layer, and an etched side surface of the first type semiconductor layer; and
using a water vapor to penetrate at least a part of the etched side surface of the second type semiconductor layer, the etched side surface of the active layer, and at least a part of the etched side surface of the first type semiconductor layer, so as to form a metal oxide in at least a part of an edge region of the second type semiconductor layer, an edge region of the active layer, and at least a part of an edge region of the first type semiconductor layer.

2. The manufacturing method of the light-emitting diode structure according to claim 1, wherein the metal oxide comprises an aluminum oxide, an indium oxide, a gallium oxide, or a combination thereof.

3. The manufacturing method of the light-emitting diode structure according to claim 1, further comprising:
forming a first electrode on the second type semiconductor layer; and
forming a second electrode on the first type semiconductor layer.

4. The manufacturing method of the light-emitting diode structure according to claim 3, further comprising forming a protective layer on the first type semiconductor layer, a side surface of the second electrode, the etched side surface of the first type semiconductor layer, the etched side surface of the active layer, the etched side surface of the second type semiconductor layer, the second type semiconductor layer, and a side surface of the first electrode.

5. The manufacturing method of the light-emitting diode structure according to claim 1, wherein the substrate is a first type semiconductor substrate, and the manufacturing method of the light-emitting diode structure further comprises:
forming a first electrode on the second type semiconductor layer; and
forming a second electrode on a surface of the substrate away from the active layer.

6. The manufacturing method of the light-emitting diode structure according to claim 1, wherein one of the first type semiconductor layer and the second type semiconductor layer is N-type, and another one of the first type semiconductor layer and the second type semiconductor layer is P-type.

7. The manufacturing method of the light-emitting diode structure according to claim 1, wherein the first type semiconductor layer comprises:
a first type semiconductor sublayer, formed on the substrate; and
a first type cladding layer, formed on the first type semiconductor sublayer, and
wherein the second type semiconductor layer comprises:
a second type cladding layer, formed on the active layer; and
a second type semiconductor sublayer, formed on the second type cladding layer, wherein the water vapor penetrates the etched side surface of the second type cladding layer, the etched side surface of the active layer, and the etched side surface of the first type cladding layer, so as to form the metal oxide in an edge region of the second type cladding layer, the edge region of the active layer, and an edge region of the first type cladding layer.

8. A light-emitting diode structure, comprising:
a substrate;
a first type semiconductor layer, configured on the substrate;
an active layer, configured on the first type semiconductor layer;
a second type semiconductor layer, configured on the active layer; and
a metal oxide layer, directly contacting an edge of at least a part of the first type semiconductor layer, an edge of the active layer, and an edge of at least a part of the second type semiconductor layer.

9. The light-emitting diode structure according to claim 8, further comprising:
a first electrode, configured on the second type semiconductor layer; and
a second electrode, configured on the first type semiconductor layer.

10. The light-emitting diode structure according to claim 9, further comprising a protective layer, the protective layer covering the first type semiconductor layer, a side surface of the second electrode, the metal oxide layer, the second type semiconductor layer, and a side surface of the first electrode.

11. The light-emitting diode structure according to claim 8, wherein the substrate is a first type semiconductor substrate, and the light-emitting diode structure further comprises:
a first electrode, configured on the second type semiconductor layer; and
a second electrode, configured on a surface of the substrate away from the active layer.

12. The light-emitting diode structure according to claim 8, wherein one of the first type semiconductor layer and the second type semiconductor layer is N-type, and another one of the first type semiconductor layer and the second type semiconductor layer is P-type.

13. The light-emitting diode structure according to claim 8, wherein the first type semiconductor layer comprises:
a first type semiconductor sublayer, configured on the substrate; and
a first type cladding layer, configured on the first type semiconductor sublayer, and
wherein the second type semiconductor layer comprises:
a second type cladding layer, configured on the active layer; and
a second type semiconductor sublayer, configured on the second type cladding layer, wherein the metal oxide layer directly contacts an edge of the first type cladding layer, the edge of the active layer, and an edge of the second type cladding layer.

14. The light-emitting diode structure according to claim 8, wherein a material of the metal oxide layer comprises an aluminum oxide, an indium oxide, a gallium oxide, or a combination thereof.
